(19) United States
(12) Patent Application Publication
(10) Pub. No.: US 2026/0319004 A1
(43) Pub. Date: Oct. 15, 2026

(54) METHOD AND SYSTEM FOR CORRECTION OF IMPEDANCE MEASUREMENT

(71) Applicant: TEXAS INSTRUMENTS INCORPORATED, Dallas, TX (US)

(72) Inventors: David MAGEE, Allen, TX (US); Bassem IBRAHIM, Allen, TX (US); Matthew GUIBORD, NORTHVILLE, MI (US)

(21) Appl. No.: 19/379,378

(22) Filed: Nov. 4, 2025

Related U.S. Application Data
(60) Provisional application No. 63/785,877, filed on Apr. 9, 2025.

(51) Int. Cl. G01R 31/389; G01R 31/3842; G01R 31/396; H01M 10/42

(52) U.S. Cl. CPC G01R 31/389; G01R 31/3842; G01R 31/396; H01M 10/4285

(57) ABSTRACT

A system includes: a device under test (DUT) packaged in an assembly; a voltage measurement circuit coupled to the DUT and configurable to obtain a voltage measurement representing a voltage across the DUT; a current measurement circuit coupled to the DUT and configurable to obtain a current measurement representing a current through the DUT; and a processing circuit coupled to the voltage measurement circuit and the current measurement circuit. The processing circuit is configurable to: receive the voltage measurement; receive the current measurement; and compute an impedance spectrum of the DUT responsive to the voltage measurement, the current measurement, and parameters specific for the assembly.

### CROSS-REFERENCE TO RELATED APPLICATIONS

This application claims priority to U.S. Provisional Application No. 63/785,877, filed Apr. 9, 2025, titled “Offset Calibration Method Using an Average DUT Impedance Response to Correct an Impedance Measurement,” which is hereby incorporated by reference by its entirety.

This application is also related to U.S. application Ser. No. 19/041,746, filed Jan. 30, 2025, titled “Method and System for Calibration and Correction of an Impedance Measurement,” which is also hereby incorporated by reference by its entirety.

### BACKGROUND

Rechargeable batteries are essential for powering many electronic and portable electronic devices such as electric vehicles, laptop computers, and mobile phones. Battery behavior during charging and discharging varies throughout the life of the battery and depends upon battery cell states as well as environmental effects. Prediction of battery cell behavior during its run time is important to manage and improve the power supplied by batteries during operation. The battery condition is often characterized by the level of available charge, known as state-of-charge (SoC), and the percentage of useful charge/discharge cycles that remain, known as state-of-health (SoH) for each cell in the battery. The prediction of battery cell parameters such as SoC, SoH and temperature relies on mathematical models of the battery cell that can be used to estimate these parameters based on the chemical state of each cell.

### SUMMARY

In an example, a system includes: a device under test (DUT) packaged in an assembly; a voltage measurement circuit coupled to the DUT and configurable to obtain a voltage measurement representing a voltage across the DUT; a current measurement circuit coupled to the DUT and configurable to obtain a current measurement representing a current through the DUT; and a processing circuit coupled to the voltage measurement circuit and the current measurement circuit. The processing circuit is configurable to: receive the voltage measurement; receive the current measurement; and compute an impedance spectrum of the DUT responsive to the voltage measurement, the current measurement, and parameters specific for the assembly.

In another example, a system includes: a first DUT packaged in an assembly; a voltage measurement circuit coupled to the first DUT and configurable to obtain a measurement of voltage across the first DUT; a current measurement circuit coupled to the first DUT and configurable to obtain a measurement of current through the first DUT; and a processing circuit coupled to the voltage measurement circuit and the current measurement circuit. The processing circuit is configurable to: receive the voltage measurement; receive the current measurement; and compute an impedance spectrum of the first DUT responsive to the voltage measurement, the current measurement, and a reference impedance spectrum of a second DUT, in which the second DUT is not in the assembly.

In yet another example, an apparatus includes a processing circuit having a voltage measurement input and a current measurement input. The processing circuit is configurable to: receive, at the voltage measurement input, a voltage measurement representing a voltage across a DUT in an assembly; receive, at the current measurement circuit input, a current measurement representing a current through the DUT in the assembly; and compute an impedance spectrum of the DUT responsive to the voltage measurement, the current measurement, and at least one of: parameters specific for the assembly, or a reference impedance of the DUT.

In yet another example, a method includes: obtaining a first impedance spectrum of a DUT removed from an assembly; determining a second impedance spectrum of the DUT packaged in the assembly; and providing parameters specific for the assembly responsive to a difference between the first and second impedance spectrums.

### BRIEF DESCRIPTION OF THE DRAWINGS

FIG. 1A is a flowchart showing a method of performing a monitoring operation of a device under test (DUT), according to various examples.

FIG. 1B is a schematic diagram showing an equivalent circuit model (ECM) for a battery cell, according to various examples.

FIG. 2 is a diagram showing a battery monitoring system, according to various examples.

FIGS. 3 to 5 are diagrams showing internal components of a battery monitoring system and their operations, according to various examples.

FIGS. 6 and 7 are flowcharts showing methods of performing impedance spectroscopy of a device under test (DUT), according to various examples.

FIGS. 8A to 8D are graphs showing improvements in impedance errors provided by techniques described herein, according to various examples.

FIG. 9 is a block diagram of an example processor platform including processor circuitry structured to execute machine-readable instructions to implement the circuits and unit depicted in the examples above.

### DETAILED DESCRIPTION

The same reference numbers or other reference designators are used in the drawings to designate the same or similar features. Such features may be the same or similar either by function and/or structure.

As described herein, a DUT may include any electrochemical device that has an electrical impedance, a charge storage device (e.g., a battery cell or a capacitor), or a device having a non-uniform frequency response. The DUT may be characterized by a sensing system (e.g., a voltage measurement circuit, a current measurement circuit, etc.) to obtain a frequency response (e.g., an impedance spectrum) of the DUT. The DUT can be part of a module (e.g., a battery module) or a pack (e.g., a battery pack) that includes multiple instances of the DUTs (e.g., multiple instances of a battery cell) electrically coupled together. The DUT can also be part of an assembly that can include any physical hardware and connections from and including the sensing system to the DUTs. For example, for automotive, an assembly can be a battery module or a battery pack coupled to a sense board. For an energy storage system, an assembly can include multiple battery cells (or other charge storage elements) coupled to a sense board.

The DUTs of an assembly can be characterized using electrochemical impedance spectroscopy (EIS) to obtain an impedance spectrum of the DUTs. In a case where the DUT is a battery cell, the EIS can be performed to determine various states of the battery cell, such as SoH, SoC, temperature, etc., to support a battery monitoring and/or management operation. The EIS can be performed by, for example, providing a current to each battery cell of the battery module to obtain a voltage across the battery cell. The voltage and current across each battery cell can be measured (e.g., by voltage and current measurement circuits, respectively), and a ratio between the measured voltage and current of each battery cell, which represents an impedance of the battery cell, can be computed. The frequency of the current provided to the battery cell can be varied, and the impedance of the battery cell can be determined at different frequencies to provide an impedance spectrum.

There can be error components in the impedance spectrum that do not represent the electrochemistry of the DUT. The error components can be introduced in the voltage measurement due to, for example, various parasitics within the assembly. For example, a battery module includes multiple battery cells. The battery cells are welded to brackets and wiring harnesses. The wiring harness can be relatively long and can have mutual inductance. As a current pass through the wiring harness, the current can introduce a voltage across the voltage measurement circuit due to the mutual inductance. The voltage can add a component to the actual impedance spectrum, and the error component varies with frequency. As another example, the welded plates to the cell terminals can introduce additional capacitance. This capacitance can also introduce a component in the impedance spectrum that varies with frequency. As another example, the resistance of board traces of the sense board and wiring (wires, flex cable, etc.) can introduce a bias in the real portion of the impedance spectrum. Any resistance, inductance and capacitance that arise from the physical construction of the circuit boards, battery interconnects and impedance sensing that are not associated with the electrochemistry and the corresponding impedance response of the battery cell are considered to be parasitics. These components do not represent the electrochemistry of the battery cell and represent error components in the impedance spectrum. Other parasitics external to the battery module but within the assembly, such as mutual inductance between wirings to the voltage measurement circuits that are external to the battery module, may also add error components to the impedance spectrum. Those error components can be in the form of an offset function that is a function of frequency, where frequency contents unrelated to the electrochemistry of the battery cell are added to the impedance spectrum.

In addition, as described in the related U.S. application Ser. No. 19/047,746 (hereinafter, '746 application), the measurement circuitry used to measure various electrical quantities of the battery cell, such as voltage measurement circuitry and current measurement circuitry to provide, respectively, voltage and current measurements used to compute the impedance spectrum, can introduce additional errors to the impedance spectrum, For example, the measurement circuit may include low-pass filters to reduce noise. The cut-off frequency of the low-pass filters may be close to the sampling frequency of the measurement circuit, which may cause amplitude and phase shifts in the measured signals. These phase shifts result in a phase error in the measured impedance. In addition, the parasitic inductance at the electrical interface and wiring between the battery module and the measurement circuit (in addition to the aforementioned mutual inductance) can also cause ringing with any switching activity (e.g., from an excitation circuit that generates the stimulus for the EIS), and the ringing results in signal distortion, and filtering circuitry to attenuate the ringing can lead to the measured current being different from the actual battery cell current in amplitude and phase, causing an additional source of error in the impedance spectrum. The impact of the measurement circuit on the impedance spectrum can be in the form of a gain function (or a gain distortion function) that can introduce distortions by scaling the impedance spectrum with a scaling factor that is a function of frequency.

In some examples, a DUT (e.g., a battery cell) can be characterized in multiple settings to obtain parameters for eliminating or at least mitigating the effects of parasitics. For example, a first EIS operation can be performed on the battery cells of a battery module (or an assembly) without the battery cells removed from the battery module/assembly (e.g., not welded to brackets and wiring harnesses of the battery module), to obtain a reference impedance spectrum of the battery cells. In the first EIS operation, the voltage and current measurements can be performed with dedicated and high-precision measurement hardware in a well-controlled environment (e.g., in a laboratory) that do not introduce the aforementioned gain distortion errors. Accordingly, the reference impedance spectrum may not have the aforementioned error components introduced by the mutual inductance between wirings and the capacitance between the welded plates to the cell terminals, or otherwise have a substantially attenuated version of the error components. The reference impedance spectrum may also not have the aforementioned distortions. In some examples, the first EIS operation can be performed over multiple battery cells, and the impedance spectrums of the multiple battery cells can be averaged to generate the reference impedance spectrum of a battery cell.

After the battery cells are packaged into the battery module and welded to brackets and wiring harnesses, a second EIS operation can be performed on the battery module to determine raw impedance spectrums of the battery cells in the battery module. The second EIS operation can be performed using the voltage and current measurement circuits of a battery monitoring/management system and will be used in subsequent EIS operations to supporting an on-going battery monitoring/management system. The aforementioned gain function (or gain distortion function) of the voltage and current measurement circuits, described in the related 746 application, is also pre-determined in a prior calibration operation. The raw impedance spectrum obtained from the second EIS operation may also have the aforementioned error components introduced by the mutual inductance between wirings and the capacitance between the welded plates to the cell terminals. The raw impedance spectrum obtained from the second EIS operation can be combined with an inverse of the gain function to generate distortion-compensated raw impedance spectrum, in which the distortion caused by the measurement circuits can be removed or at least attenuated.

Following the generation of the distortion-compensated raw impedance spectrum, parameters of the offset function, representing the error components introduced by the packaging and are specific for the battery module, can be obtained based on a difference between the distortion-compensated raw impedance spectrum of each battery cell (obtained from the second EIS operation) and the reference impedance spectrum (obtained from the first EIS operation). The parameters can then be used to combine with raw impedance spectrums of this battery module, or other battery modules having the same configuration (e.g., having the same number of battery cells, same packaging, same brackets, same wiring harnesses, of the same battery module model/specification, etc.) obtained in subsequent EIS operations to remove (or at least reduce) the error components from those impedance spectrums introduced by the mutual inductance between wirings and the capacitance between the welded plates to the cell terminals, to obtain compensated impedance spectrums. The compensated impedance spectrums can be used to provide an equivalent circuit model (ECM) of the battery cells to support a battery monitoring and/or management operation of the battery module.

With the described techniques, error components in the impedance spectrum of a battery cell introduced by the mutual inductance between wirings and the capacitance between the welded plates to the cell terminals of a battery module can be eliminated or at least reduced. Accordingly, the impedance spectrum and the ECM obtained from the impedance spectrum can more accurately reflect the various states (e.g., SoC, SoH, temperature) of the battery cells. This model in turn can improve the accuracy of the monitoring operation as well as the management operation of the battery module.

In various examples described herein, the DUT includes a battery cell. Other examples of a DUT may include any electrochemical device that has an electrical impedance, a charge storage device (e.g., a capacitor), or other devices having a frequency response. Although a battery or a battery module is used as a non-limiting example of a DUT in the discussions below, the same or similar approaches are also appliable to measurement of other types of DUTs. Furthermore, although impedance spectroscopy is used as a non-limiting example of frequency response measurement in the description below, the same or similar approaches are also applicable to measurements of any frequency response of a DUT. For example, cells of a DUT can be determined when the cells are not packaged in the DUT to determine a reference frequency response, followed by characterizing the cells when being packaged in the DUT to determine a raw frequency response. Parameters representing error components can be determined based on a difference between the raw and reference frequency responses. The parameters can be combined with raw frequency responses determined in subsequent characterization operations to eliminate/reduce the error components.

Various states/conditions of a DUT (e.g., a battery cell) may include the level of available charge, known as state-of-charge (SoC), and the percentage of useful charge/discharge cycles that remain, known as state-of-health (SoH), and temperature. State parameters such as SoC, SoH, and temperature, can be determined using mathematical models of the battery cell that can be used to estimate these parameters based on the chemical reactions inside each cell. An example battery cell mathematical model may include an equivalent circuit model (ECM) with resistor and capacitor elements to model the battery cell behavior under different conditions. As the battery cells age, the values of the ECM elements will change over time.

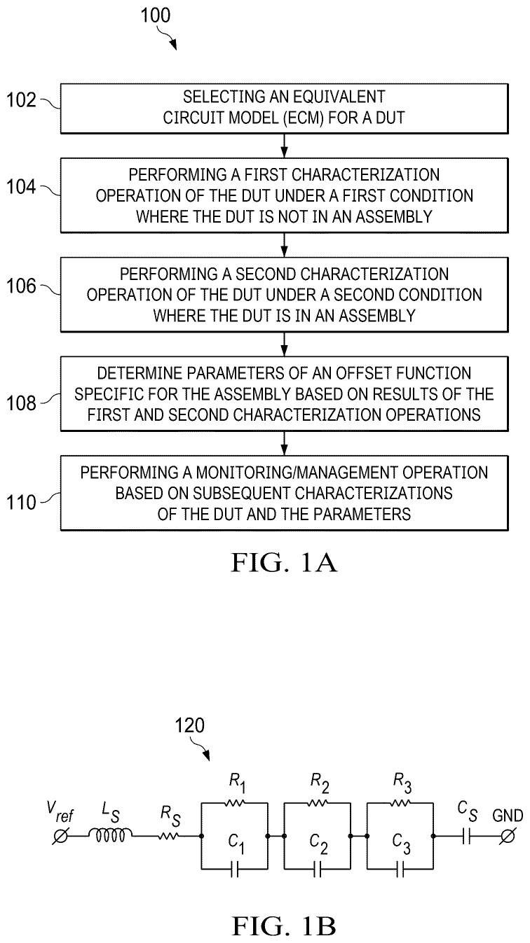

The electro-chemical effects that occur inside a DUT during charging, discharging, and aging can be represented using an ECM. The ECM can be used to determine a state of the battery cell to support a monitoring and/or management operation of the battery cell. FIG. 1A is a flowchart showing an example of a method 100 of performing a battery monitoring operation of a battery module. The method 100 includes selecting an equivalent circuit model (ECM) for a DUT at block 102. FIG. 1B is an example schematic diagram shown an ECM 120 for a battery cell. In the example of FIG. 1B, the ECM 120 includes a series combination of a capacitor Cₛ, a resistor Rₛ, an inductor Lₛ, and RC stages, each RC stage including a respective resistor (e.g., R₁, R₂, R₃) and a respective capacitor (e.g., C₁, C₂, C₃) connected in parallel. The series capacitor Cₛ represents the charge stored in the battery cell, the series resistor Rₛ represents the direct-current (DC) resistance of the battery cell, and each of the RC stages represent the instantaneous voltage behavior during different phases of the electro-chemical process. In some examples, the impedance of a battery cell is determined from an ECM (e.g., the ECM 120 or another ECM) once related parameter values have been determined using a characterization method.

Referring again to FIG. 1A, in block 104, a first characterization operation of the DUT under a first condition is performed. In some examples, the operations of block 104 include determining a reference spectroscopy (e.g., a reference impedance spectrum), which can include measurements of an impedance or other properties at different excitation frequencies, for the DUT. The first characterization operation may be a first EIS operation performed in the first condition where the DUT is removed from an assembly/module—for example, not coupled to a sense board in an assembly, not packaged in a module (e.g., a battery module), or is otherwise removed from the module—so that the reference spectroscopy is substantially free of error components that would otherwise be introduced by parasitics in the module package. For example, the first EIS operation can be performed on the battery cells of a battery module without the battery cells being welded to brackets and wiring harnesses of the battery module, to obtain a reference impedance spectrum of the battery cells. In some examples, the first characterization involves measuring the impedance response of one or more battery cells using an impedance analyzer, or dedicated and high-precision measurement hardware in a well-controlled environment (e.g., in a laboratory) that do not introduce the aforementioned gain distortion errors.

The reference spectroscopy may not have the error components introduced by the mutual inductance between wirings and the capacitance between the welded plates to the cell terminals, or otherwise have a substantially attenuated version of the error components. Also, the reference spectroscopy may not have the distortion error, or a substantially attenuated version of the distortion error compared with a case where the voltage and current measurements are performed with a battery monitoring/management system.

In one example, the reference spectroscopy can be obtained by averaging spectroscopy results of multiple instances of the battery cells (e.g., battery cells of the same model and/or having the same electrochemistry). In another example, the reference spectroscopy can be obtained by averaging spectroscopy results from multiple characterizations of a battery cell.

In block 106, a second characterization operation of the DUT is performed under a second condition. The second characterization operation may be a second EIS operation performed in the second condition where the DUT is coupled to other components in an assembly, packaged in a module (e.g., a battery module) where the battery cells are welded to brackets and connected to wiring hardnesses of the battery module, or otherwise being wired in a target configuration (e.g., a vehicle or other modular power system). Parasitics in the package and/or in the target configuration, such as the mutual inductance between wirings and the capacitance between the welded plates to the cell terminals, can add error components unrelated to the electrochemistry of the DUT to the impedance spectrum. The error components can be in the form of an offset function and is a function of frequency.

In addition, in some examples, the second EIS operation can be performed with the voltage and current measurement circuits of a battery monitoring/management system that can introduce gain distortion error to the impedance spectrum, as described above. In such examples, a raw impedance spectrum, including the error components in the form of an offset function and being scaled with a gain distortion function, can be determined from the second EIS operation. In some examples, the second EIS operation can also be performed with the same system used for the first EIS operation. In such examples, the raw impedance spectrum may not be scaled with the gain distortion function.

In block 108, parameters of the offset function can be determined based on, for example, a difference between the raw impedance spectrum and the reference impedance spectrum. In a case where the second EIS operation introduces distortion, the raw impedance spectrum can be scaled by an inverse of the gain distortion function to compensate for the distortion, and the offset function can be determined based on a difference between the distortion-compensated raw impedance spectrum and the reference impedance spectrum.

Parameters of the offset function specific for the battery module and/or the target configuration can be stored in a data storage. Blocks 102-108 can be repeated for different battery modules and/or different target configurations. In some examples, the parameters can be stored in a database and associated with different battery module configurations (e.g., different battery module models, different number of battery cells, different brackets and wiring configurations, etc.). In some examples, the parameters can be part of a battery management/monitoring system firmware, and firmware for each battery module model/configuration can have a different set of offset function parameters specific for that battery module model/configuration.

At block 110, a battery monitoring/management operation can be performed based on subsequent characterization operations of the module (or other instances of the module) and the parameters. Specifically, a subsequent EIS operation can be performed on the module, and raw impedance spectrum of the battery cells in the module can be obtained from the EIS operation. The raw impedance spectrum from the subsequent EIS operations can be scaled with an inverse of the gain distortion function (or gain function) to generate the distortion-compensated impedance spectrum. Also, parameters of the offset function specific for the battery module configuration can be obtained (e.g., from a database, or can be part of battery monitoring/management operation firmware specific for the battery module configuration), and can be combined with the distortion-compensated raw impedance spectrum from the subsequent EIS operation to generate an offset-compensated and distortion-compensated impedance spectrum. Various model parameters of the battery cells, such as the values of Cₛ, Rₛ, Lₛ, R₁, R₂, R₃, C₁, C₂, and C₃ can be determined from the compensated impedance spectrum. From the model parameters, various state parameters of the battery cells/module, such as SoC, SoH, temperature, can be determined as part of the battery monitoring operation. Additional actions, such as charging/discharging of the battery cells, can also be performed as part of the battery management operation.

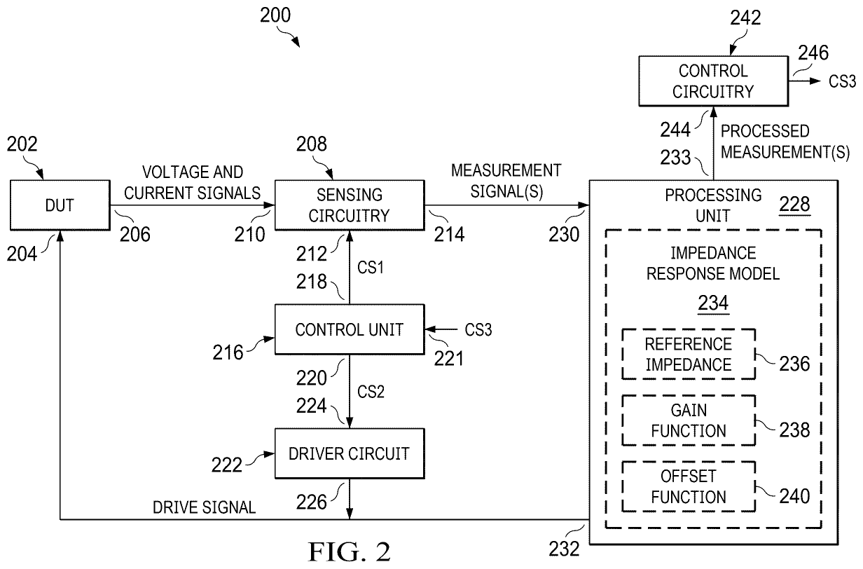

FIG. 2 is a diagram showing an example system 200. The system 200 includes a DUT 202, sensing circuitry 208, a control unit 216, a driver circuit 222, a processing unit 228, and control circuitry 242 in the arrangement shown. The DUT 202, which can be a battery cell packaged in a battery module, includes a first terminal 204 and second terminal 206. The sensing circuitry 208 includes a first terminal 210, a second terminal 212, and a third terminal 214. The control unit 216 includes a first terminal 218, a second terminal 220, and a third terminal 221. The driver circuit 222 incudes a first terminal 224 and a second terminal 226. The processing unit 228 includes a first terminal 230, a second terminal 232, and a third terminal 233. The control circuitry 242 has a first terminal 244 and a second terminal 246.

In the example of FIG. 2, the first terminal 204 of the DUT 202 and the second terminal 232 of the processing unit 228 are coupled to the second terminal 226 of the driver circuit 222. The second terminal 206 of the DUT 202 is coupled to the first terminal 210 of the sensing circuitry 208. The second terminal 212 of the sensing circuitry 208 is coupled to the first terminal 218 of the control unit 216. The third terminal 214 of the sensing circuitry 208 is coupled to the first terminal 230 of the processing unit 228. The second terminal 220 of the control unit 216 is coupled to the first terminal 224 of the driver circuit 222. The third terminal 233 of the processing unit 228 is coupled to the first terminal 244 of the control circuitry 242. The second terminal 246 of the control circuitry 242 is coupled to the third terminal 221 of the control unit 216.

In the example of FIG. 1, the processing unit 228 has access to an impedance response model 234. The impedance response model 234 includes a reference impedance 236, a gain function 238, and an offset function 240. One of reference impedance 236 or offset function 240 can be optional.

In some examples, the reference impedance 236 is the reference impedance spectrum of the DUT 202 obtained by averaging impedance results from the EIS operations of multiple battery cells, or multiple EIS operations of a battery cell, as described in block 102 of FIG. 1B. The reference impedance 236 can be used to compute offset function 240. Accordingly, in some examples, the reference impedance 236 can be omitted from the impedance response model 234 if offset function 240 is present in the impedance response model 234.

In some examples, the gain function 238 can be an inverse of a gain distortion function that can be introduced to the impedance measurements by the sensing circuitry 208, as explained above. In some examples, as explained in the related '746 Application, the gain function 238 is obtained using a reference component with a known impedance (e.g., a precision resistor) and a wiring configuration that minimizes or eliminates the mutual inductance of each measurement (i.e., offset due to wiring/DUT configuration is minimized). As part of a calibration operation, a known current can flow through the precision component in place of the DUT at different frequencies, and the voltage across the precision component, as well as the current that flows through the precision component, can be measured by the sensing circuitry 208. An impedance spectrum can be computed from the measured voltage and current. The gain function, which is also a function of frequency, can be computed based on a ratio between the impedance spectrum and the known impedance at different frequencies. The gain function can be specific for the sensing circuitry 208 or a particular system (e.g., 200) including the sensing circuitry 208. The gain function can be used to compensate for gain distortion error in the measured impedance introduced by the sensing circuitry 208.

In some examples, the offset function 240 can represent the error components introduced by parasitics of the battery module package and/or in the target configuration of the battery module, such as the mutual inductance between wirings and the capacitance between the welded plates to the cell terminals, obtained from block 108 of FIG. 1B (e.g., see equation 17 herein). The offset function 240 can be specific for a particular battery module model and/or a particular target configuration (e.g., in a particular vehicle model). The offset function 240 can be used to compensate for error components added to the measured impedance by the parasitics. The offset function 240 can be derived from the reference impedance 236 and the measured impedance (e.g., if both impedances are obtained under the same state condition (e.g., same SoH, same SoC, same temperature, etc.). Accordingly, in some examples, the offset function 240 can be omitted if the reference impedance 236 is present in the impedance response model 234.

In some examples, reference impedance 236, gain function 238, and offset function 240 can be in the form of parameters input (e.g., from registers) to processing unit 228 to perform EIS operations. In some examples, reference impedance 236, gain function 238, and offset function 240 can be part of firmware codes to be executed by a processor to implement the function of processing unit 228. The processor can execute the firmware code including the offset function 240 specific for a particular battery module including the DUT 202, the reference impedance of the DUT 202, and the gain function 238 specific for the sensing circuitry 208.

In the example of FIG. 2, the DUT 202 is monitored using the sensing circuitry 208, the control unit 216, the driver circuit 222, the processing unit 228, and the control circuitry 242. During monitoring operations of the DUT 202, EIS measurements are obtained using an excitation current. In some examples, the excitation current is a sinusoidal current to excite the DUT 202. In some examples, the control unit 216 operates to: receive a control signal CS3 at the third terminal 221; provide a control signal CS1 to the sensing circuitry 208 responsive to the control signal CS3; and provide a control signal CS2 to the driver circuit 222 responsive to the control signal CS3. In some examples, CS3 is a test control signal, CS1 is an enable signal, and CS2 is an excitation control signal. The driver circuit 222 operates to: receive CS2 at the first terminal 224; and provide an excitation current at the second terminal 226 responsive to CS2. The sensing circuitry 208 operates to: receive CS1 at the second terminal 212; receive voltage and current signals from the DUT 202 at the first terminal 210 while the DUT 202 is driven by excitation current; and provide measurements at the third terminal 214 responsive to measured voltage and current signals. The processing unit 228 operates to: receive the measurements at the first terminal 230; receive the excitation current at the second terminal 232; and provide processed measurements at the third terminal 233 responsive to the measurements, the excitation current or related parameters, and the impedance response model 234. In some examples, the DUT 202 is a battery cell and the processed measurements are EIS measurements.

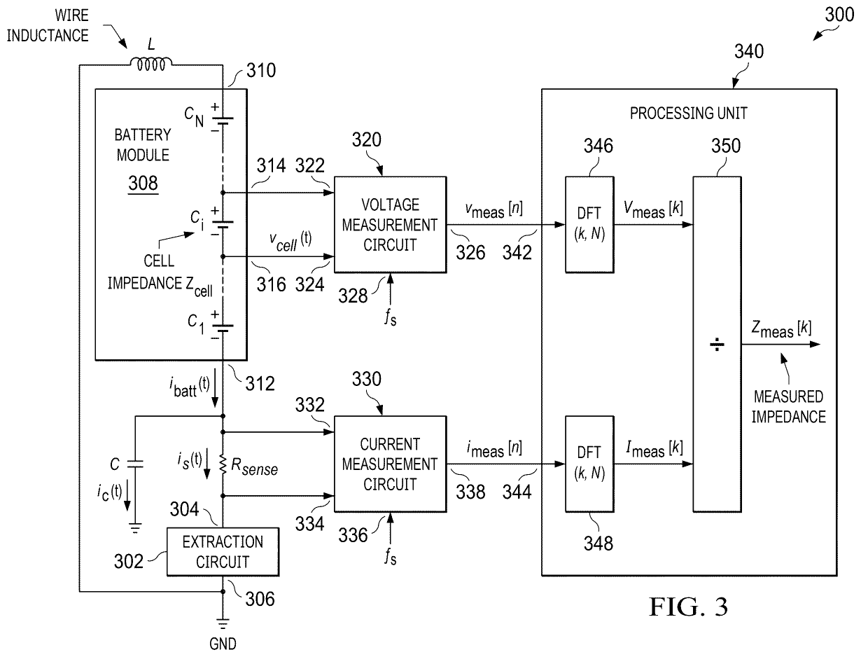

FIGS. 3 to 5 are diagrams showing example battery monitoring systems 300, 400, and 500. In the example of FIG. 3, the battery monitoring system 300 includes an excitation circuit 302, an inductor L to represent the wire inductance, a battery module 308, a resistor Rsense, a capacitor C_1, a voltage measurement circuit 320, a current measurement circuit 330, and a processing unit 340. The battery module 308 includes battery cells, represented as cells C₁ to C_{N} and including cell Cᵢ. In the example of FIG. 3, the excitation circuit 302 has a first terminal 304 and a second terminal 306. The inductor L has a first terminal and a second terminal and corresponds to the wire inductance between the excitation circuit 302 and the battery module 308. The battery module 308 has a first terminal 310, a second terminal 312, a third terminal 314, and a fourth terminal 316. The resistor Rsense has a first terminal and a second terminal. The capacitor C_1 has a first terminal and a second terminal. The voltage measurement circuit 320 has a first terminal 322, a second terminal 324, a third terminal 326, and a fourth terminal 328. The current measurement circuit 330 has a first terminal 332, a second terminal 334, a third terminal 336, and a fourth terminal 338. The processing unit 340 has a first terminal 342 and a second terminal 344. In the example of FIG. 3, the processing unit 340 includes first discrete Fourier transform (DFT) circuitry 346, second DFT circuitry 348, and divider circuitry 350. The processing unit 340 may also include the impedance response model 234 described in FIG. 2.

In the example of FIG. 3, the first terminal 304 of the excitation circuit 302 is coupled to the first terminal of the resistor Rsense and the second terminal 334 of the current measurement circuit 330. The second terminal of the resistor Rsense is coupled to the first terminal 332 of the current measurement circuit 330, the first terminal of the capacitor C_1, and the second terminal 312 of the battery module 308. The third terminal 336 of the current measurement circuit 330 is coupled to a clock with a sampling frequency (fₛ). The first terminal 310 of the battery module 308 is coupled to the first terminal of the inductor L. The second terminal of the inductor L and the second terminal 306 of the excitation circuit 302 are coupled to ground or a ground terminal. The third terminal 314 of the battery module 308 is coupled to the first terminal 322 of the voltage measurement circuit 320. The fourth terminal 316 of the battery module 308 is coupled to the second terminal 324 of the voltage measurement circuit 320. The third terminal 326 of the voltage measurement circuit 320 is coupled to a clock generator (not shown) that provides a clock signal with the sampling frequency (fₛ). In the example of FIG. 3, the battery cells C₁ to C_{N} are coupled in series between the second terminal 312 and the first terminal 310 of the battery module 308. The battery cell Cᵢ is coupled between the third terminal 314 and the fourth terminal 316. The third terminal 326 of the voltage measurement circuit 320 receives the clock signal with sampling frequency fₛ.

The fourth terminal 328 of the voltage measurement circuit 320 is coupled to the first terminal 342 of the processing unit 340. The fourth terminal 338 of the current measurement circuit 330 is coupled to the second terminal 344 of the processing unit 340. The first DFT circuitry 346 is between the first terminal 342 of the processing unit 340 and the divider circuitry 350. The second DFT circuitry 348 is between the second terminal 344 of the processing unit 340 and the divider circuitry 350.

In some examples, the excitation circuit 302 provides an excitation current. The excitation current may be a single sinusoidal signal or a linear combination of several sinusoids. These signals are referred to as single-tone or multi-tone excitation signals, respectively. In some examples, the excitation circuit 302 is directed by control signals generated by a control unit (e.g., the control unit 216 in FIG. 2) to control the timing, amplitude, frequency and phase of the excitation current. The battery voltage, which is a response to the excitation current, is measured by the voltage measurement circuit 320. The excitation current and measurement signals are typically sampled and digitally processed by the processing unit 340 or dedicated hardware. In some examples, the processing unit 340 computes a DFT of current measurements (e.g., iₘₑₐₛ[n]) from the current measurement circuit 330 and voltage measurements (e.g., vₘₑₐₛ[n]) from the voltage measurement circuit 320. In the example of FIG. 3, the divider circuitry 350 determines the ratio of the voltage DFT and the current DFT for the battery cell Cᵢ as the impedance of the battery cell Cᵢ at particular frequencies.

When measuring small impedances (e.g., on the order of 10s to 100s of uOhms) of DUTs, such as a battery cell, the parasitic impedance of the wiring and measurement circuitry has the same order of magnitude as the device impedance. Mutual inductance between excitation wires and measurement wires induces correlated error voltages due to the induced current in the measurement wiring. Further, larger currents are needed to generate the same voltage level as the impedance of the battery cells decreases. As a result, the induced voltage in the voltage measurement circuit 320 is larger for a given mutual inductance between the current and voltage sense circuits. This induced voltage is on the same order of magnitude as the cell voltage being measured, and introduce the aforementioned error components to the impedance spectrum in the form of an offset function. As to be described in more details herein, the effects of the current and voltage measurement circuits and the associated parasitics can be accounted for and compensated for, using the gain function 238 and the offset function 240 of FIG. 2, to ensure an accurate measurement of the battery cell impedances.

With the battery monitoring system 300, the excitation circuit 302 is capable of applying excitation current at excitation frequencies ωₖ to the battery module 308. The voltage measurement circuit 320 measures the battery voltage response v_{cell}(t). The current measurement circuit 330 measures the battery current signal i_{batt}(t). Ideally, the battery impedance at specific frequency ω is equal to the voltage signal divided by the current signal in frequency domain as follows:

$${Z}_{c e l l} ( j ω ) = \frac{{V}_{c e l l} ( j ω )}{{I}_{b a t t} ( j ω )} . \qquad Equation ( 1 )$$

The voltage and current measurement circuits are responsible for measuring and sampling v_{cell}(t) and i_{batt}(t) at the sampling frequency fₛ to generate discrete time voltage and current signals vₘₑₐₛ[n] and iₘₑₐₛ[n]. The measured voltage and current signals are converted to frequency domain signals of Vₘₑₐₛ(jω) and Iₘₑₐₛ(jω) at the k^{th} excitation frequency

$${ω}_{k} = 2 π k \frac{{f}_{s}}{N}$$

using a DFT, where k is the frequency bin index and N as the number of DFT points. The measured battery cell impedance Zₘₑₐₛ[k] at frequency ωₖ is computed from frequency domain signals as follows:

$${Z}_{m e a s} [ k ] = \frac{{V}_{m e a s} [ k ]}{{I}_{m e a s} [ k ]} = \frac{{V}_{m e a s} ( j ω )}{{I}_{m e a s} ( j ω )} {\vert}_{ω = {ω}_{k}} . \qquad Equation ( 2 )$$

Ideally, the measured impedance Zₘₑₐₛ[k] is equal to the actual battery impedance, Z_{cell}(jω), at the measurement frequency ωₖ if the measurement circuits provide perfect measurements. However, in reality, the measurement circuits are not ideal. The circuits have parasitics associated with board traces and wiring and can have mutual inductance components that induce voltages that can degrade the impedance measurements, especially when the induced voltage is on the same order of magnitude as the voltage coming from the cell measurement. In addition, current amplifiers (part of the current measurement circuit 330) and voltage amplifiers (part of the voltage measurement circuit 320) have magnitude error, phase error and some level of distortion across the measurement frequency range. Finally, filtering and current measurement components (e.g., resistors and capacitors) have some accuracy tolerance that is inversely proportionate to cost. All of the mentioned components will also have some variability across the operating temperature range. These error components can appear as a gain distortion function, as explained above.

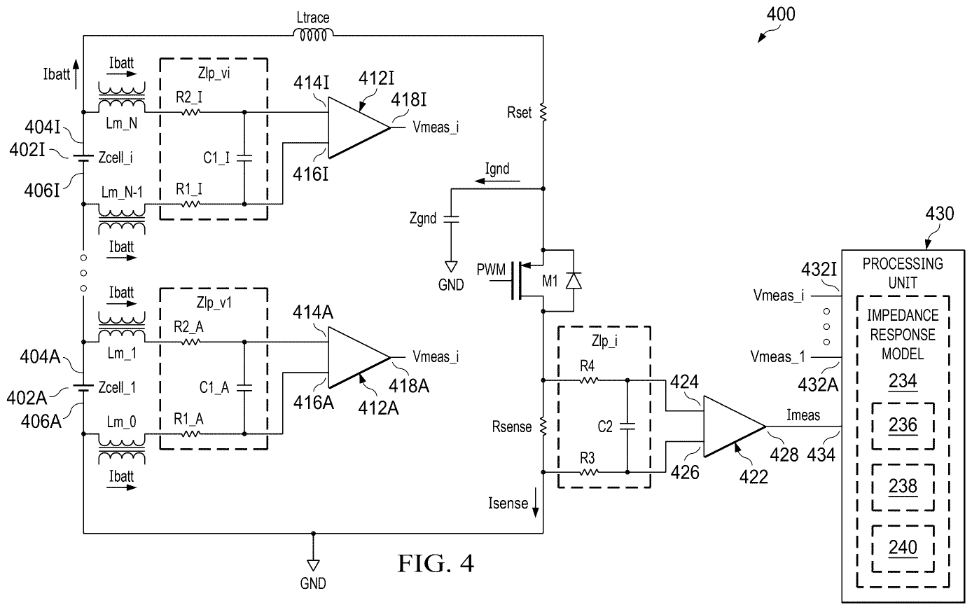

In the example of FIG. 4, the battery monitoring system 400 includes battery cells 402A to 404I, inductors Lm_0 to Lm_N, resistors R_1A to R_1I, resistors R_2A to R_2I, capacitors C_2A to C_2I, voltage measurement circuits (e.g., voltage amplifiers) 412A to 412I, an inductor Ltrace to represent the board trace inductance, a resistor Rset, an impedance Zgnd, a transistor M1, a capacitor C3, resistors R_3 and R_4, a current measurement circuit (e.g., a current amplifier) 422, and a processing unit 430 in the arrangement shown. The inductors Lm_0 to Lm_N represent the mutual inductance resulting from the magnetic field generated by the current flowing through the current path, which includes the wiring/traces between battery cells 402A to 402I, and the wiring/traces associated with the respective voltage measurement circuits 412A to 412I. In the example of FIG. 4, filter circuits (e.g., low-pass filters or LPFs) are between each of the battery cells 402A to 402I and a respective voltage measurement circuit of the voltage measurement circuits 412A to 412I. For example, the resistor R_1A, the capacitor C_2A, and the resistor R_2A form a filter circuit between the battery cell 402A and the voltage measurement circuit 412A. The resistor R_1I, the capacitor C_2I, and the resistor R_2I form a filter circuit between the battery cell 402I and the voltage measurement circuit 412I. Similar filter circuits may be used for each of the voltage measurement circuits 412A to 412I.

Each of the battery cells 402A to 404I has a respective first terminal and a respective second terminal. Each of the inductors Lm_0 to Lm_N has a respective first terminal and a respective second terminal. Each of the resistors R_1A to R_1I has a respective first terminal and a respective first terminal. Each of the resistors R_2A to R_2I has a respective first terminal and a respective first terminal. Each of the capacitors C_2A to C_2I has a respective first terminal and a respective first terminal. Each of the voltage measurement circuits 412A to 412I has a respective first terminal 414A to 414I, a respective second terminal 416A to 4161, and a respective third terminal 418A to 418I. The inductor Ltrace has a first terminal and second terminal. The resistor Rset has a first terminal and a second terminal. The impedance Zgnd has a first terminal and a second terminal. The transistor M1 has a first current terminal (e.g., a drain terminal), a second current terminal (e.g., a source terminal), and a control terminal (e.g., a gate terminal). In the example of FIG. 4, the transistor M1 is a p-channel metal oxide semiconductor (PMOS) transistor. The capacitor C3 has a first terminal and a second terminal. Each of the resistors R_3 and R_4 has a respective first terminal and a respective second terminal. The current measurement circuit 422 has a first terminal 424 and a second terminal 426. The processing unit 430 has first terminals 432A to 432I and a second terminal 434.

The first terminal 404A of the battery cell 402A is coupled to the first terminal of the inductor Lm_1. The second terminal of the inductor Lm_1 is coupled to the first terminal of the resistor R_2A. The second terminal of the resistor R_2A is coupled to the first terminal of the capacitor C_2A and the first terminal 414A of the voltage measurement circuit 412A. The second terminal 406A of the battery cell 402A is coupled to the first terminal of the inductor Lm_0. The second terminal of the inductor Lm_0 is coupled to the first terminal of the resistor R_1A. The second terminal of the resistor R_1A is coupled to the second terminal of the capacitor C_2A and the second terminal 416A of the voltage measurement circuit 412A.

The first terminal 404I of the battery cell 402I is coupled to the first terminal of the inductor Lm_N. The second terminal of the inductor Lm_N is coupled to the first terminal of the resistor R_2I. The second terminal of the resistor R_2I is coupled to the first terminal of the capacitor C_2I and the first terminal 414I of the voltage measurement circuit 412I. The second terminal 406I of the battery cell 402I is coupled to the first terminal of the inductor Lm_N−1. The second terminal of the inductor Lm_N−1 is coupled to the first terminal of the resistor R_1I. The second terminal of the resistor R_1I is coupled to the second terminal of the capacitor C_2I and the second terminal 4161 of the voltage measurement circuit 412I. The other battery cells (e.g., battery cells 402B to 402H) are likewise coupled to a respective voltage measurement circuits via respective inductors and a respective filter circuit.

In the example of FIG. 4, the first terminal 404I of the battery cell 402I is coupled to the first terminal of the inductor Ltrace. The second terminal of the inductor Ltrace is coupled to the first terminal of the resistor Rset. The second terminal of the resistor Rset is coupled to the first terminal of the impedance Zgnd and the second terminal of the transistor M1. The second terminal of the impedance Zgnd is coupled to a ground terminal. The first terminal of the transistor M1 is coupled to the first terminal of the resistor Rsense and the first terminal of the resistor R_4. The second terminal of the resistor R_4 is coupled to the first terminal of the capacitor C_3 and the first terminal 424 of the current measurement circuit 422. The second terminal of the resistor Rsense is coupled to the first terminal of the resistor R_3 and a ground terminal. The second terminal of the resistor R_3 is coupled to the second terminal of the capacitor C_3 and the second terminal 426 of the current measurement circuit 422. The resistor R_3, the capacitor C_3, and the resistor R_4 form a filter circuit (e.g., an LPF) for current measurement circuit 422. The third terminal 428 of the current measurement circuit 422 is coupled to the second terminal 434 of the processing unit 430. The third terminals 418A to 418I of the voltage measurement circuits 412A to 412I are coupled to respective terminals of the first terminals 432A to 432I of the processing unit 430.

For each of the battery cell 402A to 402I, the respective positive terminals (first terminals 404A to 404I) and respective negative terminals (second terminals 406A to 406I) have some small contact resistance and capacitance with the connection component used to connect the battery cells together. For example, the connection component may be a bolt or a bracket that has been spot welded to each battery terminal. This connection component may be considered part of the battery cell impedance, Z_{cell}(jω), because there is no practical way to separate its impedance measurement from the impedance measurement of just the battery cell. In different examples, the wiring used to measure the voltage across a battery cell may be fastened to the connection element using alligator clips. In some examples, eyelets that fit around a bolt may be compressed with the connection element using a washer and bolt or spade connectors that fit onto connectors that have been spot welded onto the bracket. The wires running to each of the voltage measurement circuits will have a resistance and inductance and will have an impedance, Z_{v_wire}(jω). The respective filter circuit (e.g., R_1A/C_2A/R_2A is a first LPF, R_1I/C_2I/R_2I is a second LPF, etc.) for each of the voltage measurement circuits 412A to 412I will have some variability in its impedance response, Zlp_v1(jω) to Zlp_vi(jω) due to the variability in the components. Ideally, since no current flows through the voltage measurement wires, there is no voltage loss associated with the wire resistance and inductance. However, a voltage can be induced into each of the voltage measurement circuits 412A to 412I by the current excitation circuit. In some examples, a transformer is used to model this coupling effect and the induced voltage is modeled as a mutual inductance, which is represented by the inductors Lm_0 to Lm_N. The filter circuit formed by the resistor R_3, the capacitor C_3, and the resistor R_4 has an impedance response Zlp_i, which can be accounted for.

In some examples, the transistor M1 is controlled by a pulse-wide modulation (PWM) signal to generate an excitation current. In some examples, the PWM frequency is 20× to 50× times higher than the desired excitation frequency, which divides the excitation into narrow pulses of varying amplitude to enable approximating the excitation amplitude and frequency. The tradeoff of this approach is a reduced cost design versus harmonics that result due to the PWM switching.

The excitation currents for different excitation frequencies are used to generate voltage measurements (Vmeas_1A to Vmeas_iA) and a current measurement (Imeas1) for each excitation current. The processing unit 430 operates to: receive voltage measurements at the first terminals 432A to 432I for each excitation current; receive a current measurement at the second terminal 434 for each excitation current; and determine an impedance for each of the battery cells 402A to 402I based on the impedance response model 234 and the frequency-dependent voltage and current measurements. In the example of FIG. 4, the impedance response model 234 includes the reference impedance 236, the gain function 238, and the offset function 240 described in FIG. 2.

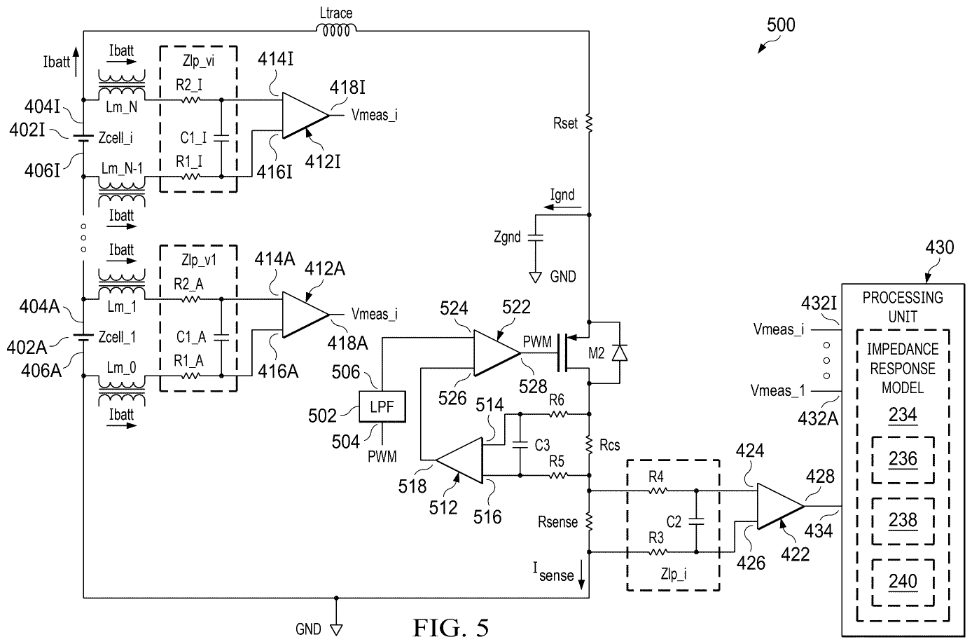

In the example of FIG. 5, the battery monitoring system 500 includes the battery cells 402A to 404I, the inductors Lm_0 to Lm_N, the resistors R_1A to R_1I, the resistors R_2A to R_2I, the capacitors C_2A to C_2I, voltage measurement circuits 412A to 412I, the inductor Ltrace which represents the trace inductance, the resistor Rset, the impedance Zgnd, the transistor M1, the resistor Rsense, the capacitor C_3, the resistors R_3 and R4, the current measurement circuit 422, and the processing unit 430 similar to the battery monitoring system 400 of FIG. 4. The battery monitoring system 500 also includes additional components including: a resistor Rcs, resistors R_5 and R_6, capacitor C_4, a first operational amplifier 512, a second operational amplifier 522, and an LPF 502. The resistor Rcs, the resistors R_5 and R_6, the capacitor C_4, the first operational amplifier 512, the second operational amplifier 522, and the LPF 502 are used to generate a pure sinusoidal excitation current without harmonics at the cost of more components.

In the example of FIG. 5, each of the resistors Rcs, R_5, R_6 has a respective first terminal and a respective second terminal. The capacitor C_4 has a first terminal and a second terminal. The first operational amplifier 512 has a first terminal 514, a second terminal 516, and a third terminal 518. The second operational amplifier 522 has a first terminal 524, a second terminal 526, and a third terminal 528. The LPF 502 has a first terminal 504 and a second terminal 506.

The first terminal of the resistor R_6 is coupled to the first terminal of the transistor M1 and the first terminal of the resistor Rcs. The second terminal of the resistor Rcs is coupled to the first terminal of the resistor R_5, the first terminal of the resistor Rsense, and the first terminal of the resistor R_4. The second terminal of the resistor R_6 is coupled to the first terminal of the capacitor C_4 and the first terminal 514 of the operational amplifier 512. The second terminal of the resistor R_5 is coupled to the second terminal of the capacitor C_4 and the second terminal 516 of the operational amplifier 512. The third terminal 518 of the operational amplifier 512 is coupled to the second terminal 526 of the second operational amplifier 522. The first terminal 504 of the LPF 502 is coupled to a PWM signal generator (not shown). The second terminal 506 of the LPF 502 is coupled to the first terminal 524 of the second operational amplifier 522. The third terminal 528 of the second operational amplifier 522 is coupled to the control terminal of the transistor M1.

In the example of FIG. 5, the path used to conduct current from the battery module for a load (e.g., the motor) and current generated by the excitation source for the purpose of EIS includes brackets, wires connecting battery cells, and traces from one or more boards that connect the excitation source and the current measurement circuit 422. The impedance associated with the current path, Z_{cp}(jω), can be modeled as a resistance in parallel with a capacitor and an inductor.

To minimize current ripple due to the excitation source and to regulate the voltage from the battery used as a reference voltage to the voltage and current measurement circuits (e.g., the voltage measurement circuits 412A to 412I and the current measurement circuit 422), one or more filters are used. The impedance of these filters is represented by Z_{gnd}(jω) since there is a current path to ground. As a result, the current measurement circuit 422 produces a measured current, iₘₑₐₛ(t) (Imeas2 in FIG. 5), which is not equal to the battery current, i_{batt}(t). For EIS operations, the difference between i_{batt}(t) and iₘₑₐₛ(t) needs to be accounted for.

One method to account for the difference between i_{batt}(t) and iₘₑₐₛ(t) is to use a calibration resistor, R_{cal}, in series with the battery cells which has a very low variability (e.g. 0.1%) and low temperature variability (e.g. ±10 PPM/° C.). In some examples, R_{cal} is used to calibrate the gain (e.g., magnitude and phase) of the battery cell impedance measurement.

The resistor Rₛₑₜ is also part of the current path to control the maximum amplitude of the current when the excitation source is commanding peak current. The resistor Rₛₑₜ can have some contact impedance resulting from solder joints, which can be modeled as a resistance and capacitance in parallel. The resistor Rsense is used to create the measured current iₘₑₐₛ(t). The resistor Rsense can have some contact impedance (e.g., resulting from the solder joints), which is modeled as a resistance and capacitance in parallel. The board traces running from the resistor Rsense to the current measurement circuit 422 have a resistance and inductance and will have an impedance, Z_{i_trace}(jω). The low pass filter (e.g., the resistors R_3 and R_4 and the capacitor C_3) before the current measurement circuit 422 will have some variation in its impedance response, Zlp_i(jω), due to the variability of the components. Ideally, since no current flows through the current measurement traces, there is no voltage loss associated with the trace resistance and inductance.

To better understand how these components impact the impedance measurements, the measured battery cell impedance, Zₘₑₐₛ(jω), will be derived and shown to be a function of the actual battery cell impedance, Z_{cell}(jω). In some examples, the measured current can be represented by the following equation:

Iₘₑₐₛ(jω)=Iₛₑₙₛₑ(jω)·G_{c}(jω), Equation (3)

where G_{c}(jω) is the gain of the current sense path, which includes the filter gain, the amplifier gain and the conversion of the voltage measurement to amperes.

$$Since {I}_{batt} = {I}_{s e n s e} + {I}_{g n d} and {I}_{g n d} ( j ω ) = \frac{{Z}_{s e n s e} ( j ω ) + {Z}_{s e t} ( j ω )}{{Z}_{g n d} ( j ω )} \cdot {I}_{s e n s e} ( j ω ) , \qquad Equation ( 4 )$$

$${I}_{s e n s e} ( j ω ) = \frac{{Z}_{g n d} ( j ω )}{{Z}_{m e a s} ( j ω ) + {Z}_{s e t} ( j ω ) + {Z}_{g n d} ( j ω )} \cdot {I}_{batt} ( j ω ) . \qquad Equation ( 5 )$$

Substituting yields:

$${I}_{m e a s} ( j ω ) = \frac{{Z}_{g n d} ( j ω )}{{Z}_{s e n s e} ( j ω ) + {Z}_{s e t} ( j ω ) + {Z}_{g n d} ( j ω )} \cdot {G}_{c} ( j ω ) \cdot {I}_{batt} ( j ω ) . \qquad Equation ( 6 )$$

By defining

$$H ( j ω ) = \frac{{Z}_{g n d} ( j ω )}{{Z}_{s e n s e} ( j ω ) + {Z}_{s e t} ( j ω ) + {Z}_{g n d} ( j ω )} \cdot {G}_{c} ( j ω ) . \qquad Equation ( 7 )$$

the measured current can be written as:

Iₘₑₐₛ(jw)=H(jω)·I_{batt}(jω). Equation (8)

Notice that H(jω) is transfer function with a magnitude and phase as a function of frequency that is independent of current.

The measured voltage Vₘₑₐₛ(jω) can be represented by the following equation:

Vₘₑₐₛ(jω)=[Z_{cell}(jω)·I_{batt}(jω)+jω·ΔLₘ·I_{batt}(jω)]·F(jω). Equation (9)

In Equation (9), ΔLₘ represents the difference in mutual inductance for a given differential voltage sense path. For example, referring to FIG. 4, for V_{meas_1A}, ΔLₘ can be a difference between Lm-1 and Lm-0.
The measured impedance can be written as:

$${Z}_{m e a s} ( j ω ) = \frac{{V}_{m e a s} ( j ω )}{{I}_{m e a s} ( j ω )} . \qquad Equation ( 10 )$$

Substituting for the measured current and voltage produces

$${Z}_{m e a s} ( j ω ) = \frac{[ {Z}_{cell} ( j ω ) \cdot {I}_{batt} ( j ω ) + j ω \cdot Δ {L}_{m} \cdot {I}_{batt} ( j ω ) ] \cdot F ( j ω )}{H ( j ω ) \cdot {I}_{b a t t} ( j ω )} , \qquad Equation ( 11 )$$

which can be re-written as:

$${Z}_{m e a s} ( j ω ) = ( {Z}_{c e l l} ( j ω ) + j ω \cdot Δ {L}_{m} ) \cdot \frac{F ( j ω )}{H ( j ω )} . \qquad Equation ( 12 )$$

In general, the measured battery cell impedance, Z_{meas_i}(jω), for the i^{th} cell is related to the actual battery impedance, Z_{cell_i}(jω), by a gain function, Gᵢ(jω), and an offset function, Oᵢ(jω),

Z_{meas_i}(jω)=(Z_{cell_i}(jω)+Oᵢ(jω)·Gᵢ(jω), Equation (13)

where

$${G}_{i} ( j ω ) = \frac{{F}_{i} ( j ω )}{H ( j ω )}$$

and Oᵢ(jω)=jw·ΔL_{m_i}.
Recalling that

$${Z}_{meas \_ i} [ k ] = \frac{{V}_{meas \_ i} ( j ω )}{{I}_{m e a s} ( j ω )} {\vert}_{ω = {ω}_{k}} ,$$

the measured battery impedance can be written as:

Z_{meas_i}[k]=(Z_{cell_i}[k]+Oᵢ[k])·Gᵢ[k], Equation (14)

where Z_{meas_i}[k] is the DFT of the measured impedance for the i^{th} battery cell, Z_{cell_i}[k] is the DFT of the impedance for the i^{th} battery cell, Gᵢ[k] is the DFT of the gain function in the battery impedance measurement due to the gain distortion error in the current and voltage measurement circuits along with the current splitting effect of the filtering and associated parasitics for the i^{th} battery cell, and Oᵢ[k] is the DFT of the offset function in the battery impedance measurement due to the mutual inductance for the i^{th} battery cell. The gain distortion error can be represented by gain function 238. The offset function can be represented by offset function 240.

In some examples, the offset function, Oᵢ[k], for each battery cell in a battery module is determined after the gain function, Gᵢ[k], is determined. The gain function, Gᵢ[k], may be determined, for example, using a reference component with a known impedance (e.g., a precision resistor), as explained above and in the related '746 application. This method for determining Gᵢ[k] relies on a wiring configuration that minimizes or eliminates the mutual inductance of each measurement so that each offset function is at or near zero.

Once the gain function is known, the offset function can be determined using a reference impedance at the battery cell location in the battery module. Since the wiring and the physical connection of each battery cell contribute to the offset function, the calibration technique accounts for these effects. In some examples, a reference impedance for a battery cell is determined. The reference impedance is an average impedance response of a battery cell as measured in a characterization test setup with minimized or known error due to mutual inductance. In some examples, the average impedance response of the cell is computed by taking an impedance response measurement for M battery cells and performing the following averaging operation:

$${Z}_{cell \_ avg} [ k ] = \frac{1}{M} \cdot {Σ}_{i = 1}^{M} Re ( {Z}_{i} [ k ] ) + j \cdot \frac{1}{M} \cdot {Σ}_{i = i}^{M} Im ( {Z}_{i} [ k ] ) , \qquad Equation ( 15 )$$

where Zᵢ[k] is the impedance response for the i^{th} battery cell. Once the average impedance response of the cell is known, the offset function for each battery cell in the module becomes:

$${O}_{i} [ k ] = {Z}_{meas \_ i} [ k ] \cdot {G}_{i}^{- 1} [ k ] - {Z}_{cell \_ avg} [ k ] . \qquad Equation ( 16 )$$

### In Equation (16),

$${G}_{i}^{- 1}$$

[k] represents an Inverse of the gain distortion function.
The corrected impedance response for the i^{th} battery cell becomes:

$${Z}_{cell \_ corr \_ i} [ k ] = {Z}_{meas \_ i} [ k ] \cdot {G}_{i}^{- 1} [ k ] - {O}_{i} [ k ] . \qquad Equation ( 17 )$$

In some examples, the impedance response model 234 described herein uses equation 17 to perform ongoing monitoring of battery cells of a battery module (e.g., in a vehicle, portable power supply, or other system with a battery module). The calculated impedance is used to determine SoC, SoH, and/or other battery health parameters.

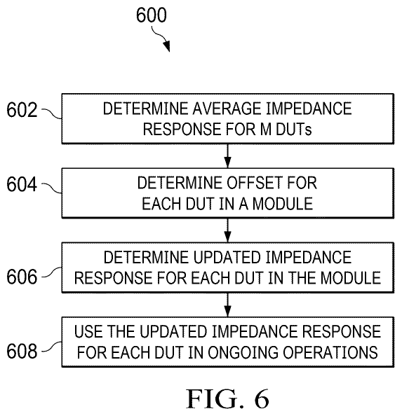

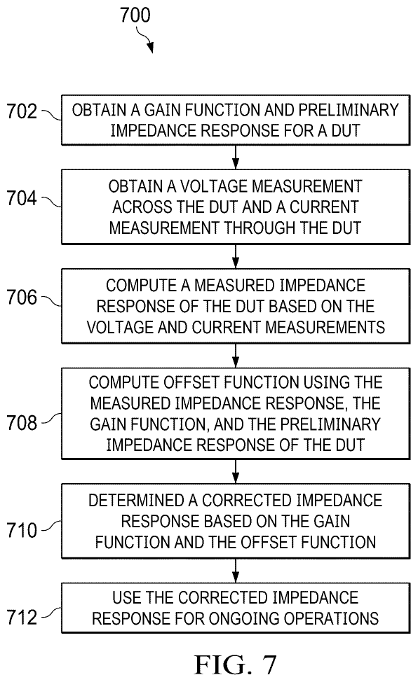

FIGS. 6 and 7 are flowcharts showing example DUT impedance monitoring methods 600 and 700. Methods 600 and 700 can be part of method 100 and can be implemented by, for example, examples of systems of FIGS. 2, 3, 4, and 5.

In the example of FIG. 6, the DUT impedance monitoring method 600 includes determining an average impedance response for M DUTs at block 602. In some examples, M is greater than 1 and less than 10. In other examples, M may be greater than 10. In some examples, the operations of block 602 use equation 15 to determine the average impedance response for M DUTs. At block 604, an offset function is determined for each DUT in an assembly (e.g., in a module, in a pack, or otherwise coupled to a sense board). The offset function includes parameters that represent error components added to the impedance spectrum of the DUT due to the parasitics in the assembly or in a module package (e.g., mutual impedance), and the offset function is specific for the assembly. In some examples, the operations of block 604 use equation 16 to determine the offset function for each DUT. At block 606, an updated impedance response is determined or each DUT in the module. In some examples, the operations of block 606 result in equation 17 being updated for each battery cell of a battery module. At block 608, the updated impedance response for each DUT is used in ongoing operations. In some examples, the ongoing operations of block 608 include: collecting voltage and current measurements for each DUT of an assembly; computing impedance of each DUT using equation 17; and determining SoC, SoH, and/or other battery health parameters based on the DUT impedance.

In the example of FIG. 7, the DUT impedance monitoring method 700 includes obtaining a gain function and preliminary impedance response for a DUT at block 702. In some examples, the gain function of block 702 is determined using a reference component with a known impedance (e.g., a precision resistor) and a wiring configuration that minimizes or eliminates the mutual inductance of each measurement (so that each offset is at or near zero). In some examples, the preliminary impedance response is the reference impedance described herein (e.g., an average impedance for a battery cell or battery cell type). At block 704, a voltage measurement across the DUT and a current measurement through the DUT is obtained. The voltage measurements Vmeas_1A to Vmeas_iA in FIG. 4 and the voltage measurements Vmeas_1B to Vmeas_iB in FIG. 5 are examples of the voltage measurements obtained at block 704. The current measurement Imeas1 in FIG. 4 or the current measurement Imeas2 in FIG. 5 are examples of the current measurement obtained at block 704. At block 706, a measured impedance response of the DUT is computed based on the voltage and current measurements. Z_{meas_i}[k] in equation 16 is an example of a measured impedance response of a DUT computed at block 706. At block 708, an offset function is computed using the measured impedance response, the gain function, and the preliminary impedance response of the DUT. In some examples, the offset is computed at block 708 using equation 16. At block 710, a corrected/compensated impedance response based on the gain function and the offset is determined. In some examples, equation 17 is used to determine the corrected impedance response at block 710. At block 712, the corrected impedance response is used for ongoing operations. In some examples, the ongoing operations of block 712 include: collecting voltage and current measurements for each battery cell of a battery module; calculating impedance of each battery cell using equation 17; and determining SoC, SoH, and/or other battery health parameters based on the calculated battery cell impedance.

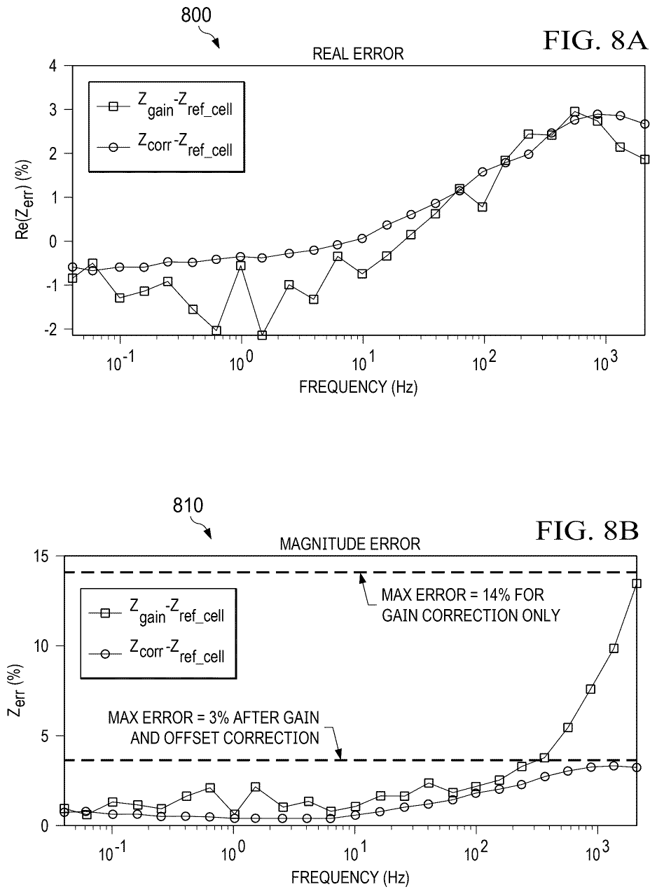

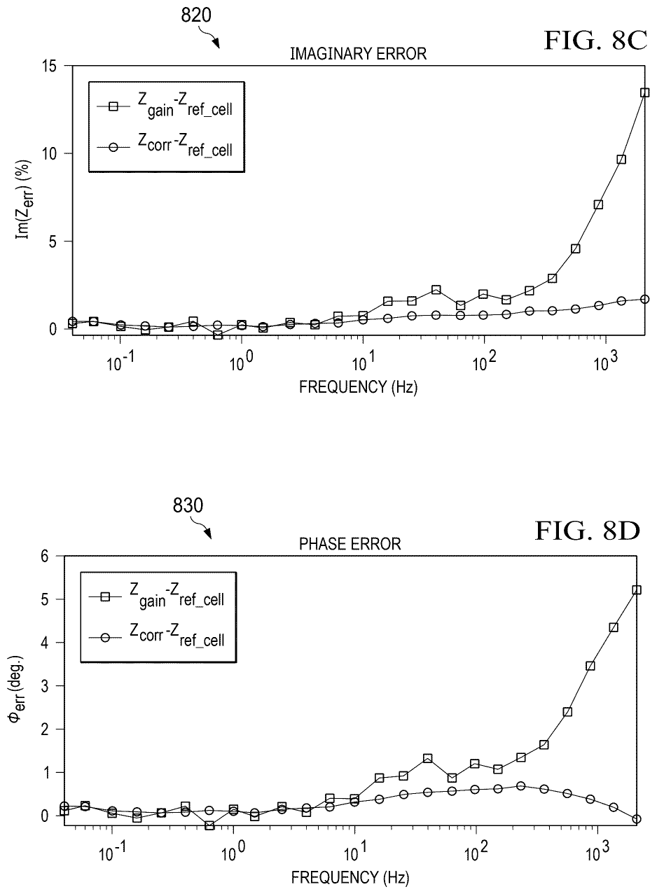

FIGS. 8A to 8D are graphs 800, 810, 820, and 830 showing error values as a function of frequency. In graphs 800, 810, 820, and 830, the error performance of using average battery cell impedance as a reference impedance as described herein is represented for 94 Ah cell connected with 2.5 m wiring harness. With just gain correction, the maximum impedance error is 14%. After applying the offset correction, the maximum impedance error is reduced to below 3%, as shown in Graph 810. Graph 830 shows that the maximum phase error is 5° after gain correction but improves to 0.5° after gain and offset correction. Graph 800 shows that the maximum error for the real part of the impedance stays unchanged after applying offset correction. Graph 820 shows the maximum error for the imaginary part of the impedance is 13% after gain correction and less than 2% after gain and offset correction.

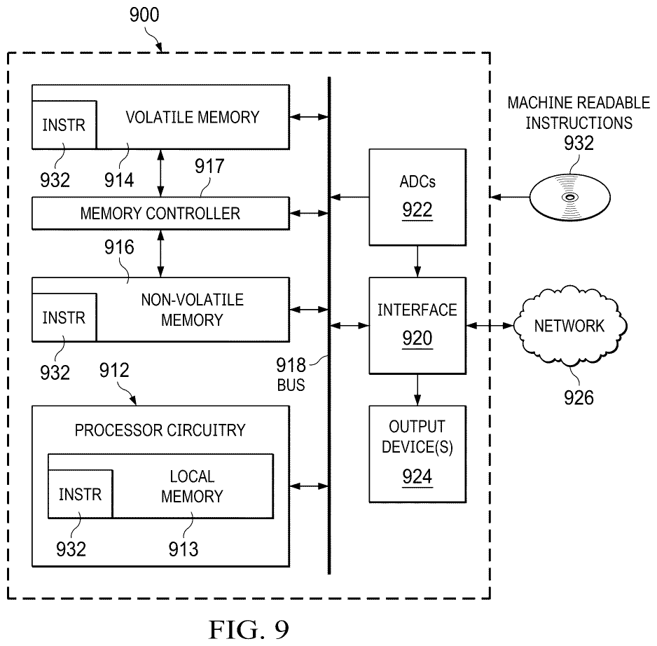

FIG. 9 is a block diagram of an example processor platform 900 including processor circuitry structured to execute machine-readable instructions to implement the circuits and unit depicted in the examples above. Processor platform 900 of the illustrated example can include processor circuitry 912. The processor circuitry 912 of the illustrated example includes hardware. For example, processor circuitry 912 can be implemented by one or more integrated circuits, logic circuits, FPGAs, microprocessors, Central Processing Units (CPUs), Graphical Processing Units (GPUs), Digital Signal Processors (DSPs), and/or microcontrollers from any desired family or manufacturer. Processor circuitry 912 can be implemented by one or more semiconductor-based (e.g., silicon-based) devices. For example, processor circuitry 912 can implement the processing unit(s) and control unit(s) discussed above.

Processor circuitry 912 of the illustrated example can include a local memory 913 (e.g., a cache, registers, etc.). Processor circuitry 912 of the illustrated example is in communication with a computer-readable storage device such as a main memory including a volatile memory 914 and a non-volatile memory 916 by a bus 918. The volatile memory 914 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by programmable read-only memory, flash memory and/or any other desired type of non-volatile memory device. Access to the main memory 914, 916 of the illustrated examples can be controlled by a memory controller 917.

The processor platform 900 of the illustrated example also includes interface circuitry 920. The interface circuitry 920 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. In the example of FIG. 9, output device(s) 924 and network 926 are coupled to the interface circuitry 920. The output device(s) 924 may include communication, user interface, or display interfaces. The network 926 may include an Ethernet channel or other network channels.

In the illustrated example, one or more ADCs 922 are connected to bus 918. The ADCs 922 can convert analog signals to digital signals for processing by the processor circuitry 912.

Machine-readable instructions 932 can be stored in volatile memory 914 and/or non-volatile memory 916. Upon execution by the processor circuitry 912, the machine-readable instructions 932 cause the processor platform 900 to perform any or all of the functionality described herein attributed to the systems and architectures discussed above, such as methods 100, 600, 700, as well as systems 200, 300, 400, and 500.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A system comprising:
a device under test (DUT) packaged in an assembly;
a voltage measurement circuit coupled to the DUT and configurable to obtain a voltage measurement representing a voltage across the DUT;
a current measurement circuit coupled to the DUT and configurable to obtain a current measurement representing a current through the DUT; and
a processing circuit coupled to the voltage measurement circuit and the current measurement circuit, the processing circuit configurable to:
receive the voltage measurement;
receive the current measurement; and
compute an impedance spectrum of the DUT responsive to the voltage measurement, the current measurement, and parameters specific for the assembly.

2. The system of claim 1, wherein the parameters are a function of frequency, and the processing circuit is configurable to:
compute a raw impedance spectrum responsive to the voltage and current measurements; and
compute the impedance spectrum based on a difference between the parameters and the raw impedance spectrum.

3. The system of claim 2, wherein the parameters represent components of the raw impedance spectrum introduced by parasitics in the assembly.

4. The system of claim 3, wherein the parasitics include at least one of: a resistance associated with the assembly, an inductance associated with the assembly, or a capacitance associated with the assembly.

5. The system of claim 2, wherein the processing circuit is configurable to compute the impedance spectrum responsive to a gain function associated with the voltage and measurement circuits.

6. The system of claim 5, wherein the gain function is a function of frequency and represents distortion introduced to the raw impedance spectrum by at least one of the voltage or current measurement circuits.

7. The system of claim 5, wherein the processing circuit is configurable to scale the raw impedance spectrum with the gain function and compute the impedance spectrum based on a difference between the parameters and the scaled raw impedance spectrum.

8. The system of claim 1, wherein the assembly is a battery module, and the DUT is a battery cell.

9. The system of claim 1, wherein the parameters are part of firmware codes executable by the processing circuit to compute the impedance spectrum.

10. The system of claim 1, wherein the processing circuit has an input and configurable to receive the parameters via the input.

11. A system comprising:
a first device under test (DUT) packaged in an assembly;
a voltage measurement circuit coupled to the first DUT and configurable to obtain a measurement of voltage across the first DUT;
a current measurement circuit coupled to the first DUT and configurable to obtain a measurement of current through the first DUT; and
a processing circuit coupled to the voltage measurement circuit and the current measurement circuit, the processing circuit configurable to:
receive the voltage measurement;
receive the current measurement; and
compute an impedance spectrum of the first DUT responsive to the voltage measurement, the current measurement, and a reference impedance spectrum of a second DUT, in which the second DUT is not in the assembly.

12. The system of claim 11, wherein the second DUT is the first DUT, and the reference impedance spectrum is obtained from the voltage and current measurements of the first DUT removed from the assembly.

13. The system of claim 11, wherein the reference impedance spectrum is based on averaging at least one of: impedance spectrums of a number of instances of the second DUT, or impedance spectrums from multiple measurement operations of the second DUT.

14. The system of claim 11, wherein the processing circuit configurable to:
compute a raw impedance spectrum of the first DUT responsive to the voltage and current measurements;
determine parameters specific for the assembly responsive to a difference between the raw impedance spectrum and the reference impedance spectrum, in which the parameters are a function of frequency; and
compute the impedance spectrum based on a difference between the parameters and the raw impedance spectrum.

15. The system of claim 14, wherein the parameters represent components of the raw impedance spectrum introduced by parasitics in the assembly, wherein the parasitics include at least one of: a resistance associated with the assembly, an inductance associated with the assembly, or a capacitance associated with the assembly.

16. The system of claim 14, wherein the processing circuit is configurable to compute the impedance spectrum responsive to a gain function associated with the voltage and measurement circuits.

17. The system of claim 16, wherein the gain function is a function of frequency and represents distortion introduced to the raw impedance spectrum by at least one of the voltage or current measurement circuits.

18. The system of claim 16, wherein the processing circuit is configurable to scale the raw impedance spectrum with the gain function and compute the impedance spectrum based on a difference between the parameters and the scaled raw impedance spectrum.

19. The system of claim 11, wherein the assembly is a battery module, and the DUT is a battery cell.

20. The system of claim 11, wherein the reference impedance spectrum is part of firmware codes executable by the processing circuit to compute the impedance spectrum.

21. The system of claim 11, wherein the processing circuit has an input and configurable to receive the reference impedance spectrum via the input.

22. An apparatus comprising:
a processing circuit having a voltage measurement input and a current measurement input, the processing circuit configurable to:
receive, at the voltage measurement input, a voltage measurement representing a voltage across a device under test (DUT) in an assembly;
receive, at the current measurement circuit input, a current measurement representing a current through the DUT in the assembly; and
compute an impedance spectrum of the DUT responsive to the voltage measurement, the current measurement, and at least one of: parameters specific for the assembly, or a reference impedance of the DUT.

23. A method comprising:
obtaining a first impedance spectrum of a device under test (DUT) removed from an assembly;
determining a second impedance spectrum of the DUT packaged in the assembly; and
providing parameters specific for the assembly responsive to a difference between the first and second impedance spectrums.
